(19) United States
(12) Patent Application Publication
(10) Pub. No.: US 2017/0250688 A1
(43) Pub. Date: Aug. 31, 2017

(54) Circuit and Method of a Level Shift Network with Increased Flexibility

(71) Applicant: Dialog Semiconductor (UK) Limited, London (GB)

(72) Inventor: Naoyuki Unno, Kanagawa (JP)

(21) Appl. No.: 15/055,871

(22) Filed: Feb. 29, 2016

(51) Int. Cl. H03K 19/00; H03K 19/0185

(52) U.S. Cl. CPC H03K 19/0013; H03K 19/018521

(57) ABSTRACT

A circuit and method for a level shift circuit with increased flexibility is described. The level shifting circuit includes an NMOS pair, a PMOS pair cross-coupled to the NMOS pair, an auxiliary transient response network parallel to the PMOS pair configured to provide a parallel current path, and a delay network configured to provide a delay to the auxiliary transient response network. Additionally, a method of providing a level shift circuit includes the steps of (a) providing an NMOS pair, (b) cross-coupling the NMOS pair to a PMOS pair, connected in parallel with an auxiliary transient response network which includes a pair of cascode PMOS, and a step (c) of providing a pair of delay inverters at inputs to the auxiliary transient response network.

### BACKGROUND

Field

The disclosure relates generally to a level shift circuit and, more particularly, to a circuit and method with improved transient response thereof.

Description of the Related Art

In electronic devices, and systems, integrated circuits operating at low supply voltages are interfaced with electronic circuits operating at higher supply voltages. For example, a chip set operating at a first core voltage level (VDD1), can interface with a memory device operating at a higher voltage level (VDD2). In such cases, a level shifting circuit (“level shifter”) can be employed to maintain communication between circuits of different supply voltage levels. Level shift circuit circuits are commonly used in semiconductor chips with multiple power supplies. Conventional level shifting circuits operate satisfactorily at low voltage ranges, but can fail at low VDD2 values and wider voltage ranges. If the first voltage (VDD1), and the second higher voltage (VDD2) vary in a wide range, parameter optimization difficult. In level shift circuits, the design parameters of interest include power consumption, semiconductor chip area, and propagation delay.

FIG. 1a shows a circuit schematic of a prior art level shift circuit. FIG. 1b to FIG. 1d illustrate three states of the prior art level shift circuit. FIG. 1b illustrates the first transition state (e.g. Transition phase 1). FIG. 1c illustrates the second transition state (e.g. Transition phase 2) of the level shift circuit. FIG 1d illustrates an inverted state of the level shift circuit.

FIG. 1a illustrates a prior art level shift circuit 100, with a high power supply voltage (VDD2) 110, and ground (VSS) 120. The circuit 100 comprises a first n-channel metal oxide semiconductor field effect transistor (NMOS) N1 140A, with NMOS gate 145A having an input IN1. The circuit 100 comprises a second NMOS N2 140B, with gate 145B having an input IN2. The circuit 100 comprises a first p-channel metal oxide semiconductor field effect transistor (PMOS) P1 130A, with its gate coupled to signal OUT2 150B. The circuit 100 comprises a second PMOS P2 130B, with gate coupled to signal OUT1 150A. FIG. 1a illustrates the state of IN1 and OUT2 150B being low (“0”) and IN2 and OUT1 150A is high (“VDD1” and “VDD2”, respectively).

FIG. 1b and FIG. 1c illustrate the transition phases when the input signals (IN1, IN2) transition from the logic state of (0,1) to (1,0). In Transition phase 1, OUT1 150A is pulled downward from VDD2 to ground (e.g. VSS) as illustrated in FIG. 1b. In FIG. 1b and subsequent drawings, transistors which are in an “off” state are shown as an open circuit. In FIG. 1b, this includes PMOS P2 130B and NMOS N2 140B. In this state, since both NMOS NI 140A and PMOS 130A are in an “on” state, the difference of the current between the two transistors (e.g. I_{N}−I_{P}) is used to pull-down OUT1. The fall time tf of OUT1 is

Cp V_{DD2}/(I_{N}−I_{P})

where Cp is a parasitic capacitance (not shown) at outputs OUT1 and OUT2. The current flow in the PMOS 130A is from VDD2 to ground (e.g. VSS). The energy loss is

V_{DD2}I_{P}{C_{P}V_{DD2}}/(I_{N}−I_{P}p)={I_{P}/(I_{N}−I_{P})}C_{P}V_{DD2}².

In Transition phase 2 the signal OUT2 150B is pulled up from ground (e.g. VSS) to VDD2 as illustrated in FIG. 1(C). In this state, the speed of the circuit is dependent on PMOS current I_{P} with the current flowing from the VDD2 to OUT2. The rise time, tr, of OUT2 is

Cp V_{DD2}/I_{P}.

The propagation delay is

C_{P}V_{DD2}/(I_{N}−I_{P})+C_{P}V_{DD2}/I_{P}

Which can be expressed as

C_{P}V_{DD2}(1/(I_{N}−I_{P})+1/I_{P)}.

as well as

C_{P}V_{DD2}I_{N}/[I_{N}²/4−(I_{N}/2−I_{P})²].

This can be expressed as greater than 1/I_{N}C_{P}V_{DD2} when I_{N}/2 equals I_{P}. When I_{N}/2 equals I_{P}, the energy loss is

{C_{P}/2}V_{DD2}²+I_{P}/(1/(2I_{P}−I_{P})+1/I_{P})C_{P}V_{DD2}²

which can be expressed as

5/2C_{P}V_{DD2}².

The propagation delay is dependent on the MOSFET channel length, and the width of both the re-channel and p-channel MOSFETs. Increasing the size of the MOSFETs, increases the current and power consumption of the circuit, which is undesirable.

FIG. 1d illustrates the “inverted state” after the transition phase 2 state. Note that this inverted state is an opposite state of the state in FIG. 1a with opposite states for IN1, IN2, OUT1, and OUT2.

The described topology in FIG. 1a to FIG. 1d, is good for understanding the d.c. and a.c. transient states. The disadvantage of this prior art embodiment is the propagation delay can only be reduced with larger MOSFET width transistors, which requires more semiconductor chip area. In addition, a second disadvantage is the propagation delay can be reduced but introduces higher power consumption.

U.S. Pat. No. 8,952,741 to Chen et al describes a level shifting circuit with an input stage, a latch and a transient speed up circuit. The transient speed up circuit comprises a delay network, a logic gate, and a p-channel MOS transistor.

U.S. Pat. No. 7,710,183 to Chaba et al shows a level shifting circuit with auxiliary circuit elements with a topology on each side of the latch comprising two additional series PMOS transistors and inverters coupled to the lower power supply configured to provide a boost to the lower power supply.

U.S. Pat. No. 7,750,719 to Chiou describes a driving circuit includes a level shifter, a buffer, and a switch. The switch is coupled between an operational voltage and a power supply terminal of a first buffer. When the level shift is operating, the switch is turned off.

U.S. Pat. No. 5,781,026 to Chow shows a level shifting circuit with first and second steady state drivers and transient driver circuit. The transient driver circuit comprises additional PMOS and NMOS in parallel with the latch network. The transient driver circuitry responds to a transition in the voltage level of the input signal by driving one of the first or second drivers.

In these prior art embodiments, the solution to establish a level switch circuit utilized various alternative solutions.

### SUMMARY

It is desirable to provide a solution to address a level shift circuit with minimal power consumption.

It is desirable to provide a solution to address a level shift circuit with minimal semiconductor chip area.

It is desirable to provide a solution to address a level shift circuit with minimized propagation delay.

A principal object of the present disclosure is to propose a solution for a level shift circuit with improved transition phase characteristics.

A principal object of the present disclosure is to propose a solution for a level shift circuit with improved propagation delays.

A principal object of the present disclosure is to propose a solution for a level shift circuit with reduced “shoot-through” current.

A principal object of the present disclosure is to propose a solution for a level shift circuit with good transition speed advantages when the first and second power supply voltages differ by a large margin.

A principal object of the present disclosure is to propose a solution for a level shift circuit with the ability to have the p-channel pair and n-channel pair design size optimization as independent variables.

The above and other objects are achieved by a level switch circuit which includes an NMOS pair, a PMOS pair cross-coupled to the NMOS pair, an auxiliary transient response network parallel to the PMOS pair configured to provide a parallel current path, and a delay network configured to provide a delay to the auxiliary transient response network.

The above and other objects are further achieved by a method of providing a level shift circuit including the steps of a first step (a) providing an NMOS pair, a second step (b) cross-coupling the NMOS pair to a PMOS pair, connected in parallel with an auxiliary transient response network which includes a pair of cascode PMOS, and a third step (c) providing a pair of delay inverters at inputs to the auxiliary transient response network.

Other advantages will be recognized by those of ordinary skill in the art.

### BRIEF DESCRIPTION OF THE DRAWINGS

The present disclosure and the corresponding advantages and features provided thereby will be best understood and appreciated upon review of the following detailed description of the disclosure, taken in conjunction with the following drawings, where like numerals represent like elements, in which:

FIG. 1a to FIG. 1d is a circuit schematic of a level shift circuit known to the inventor;

FIG. 2a to FIG. 2d is a circuit schematic in accordance with a first embodiment of the disclosure;

FIG. 3a and FIG. 3b is a timing diagram of a level shift circuit known to the inventor, and timing diagram in accordance with a first embodiment of the disclosure, respectively; and

FIG. 4 is a method in accordance with a first embodiment of the disclosure.

### DETAILED DESCRIPTION

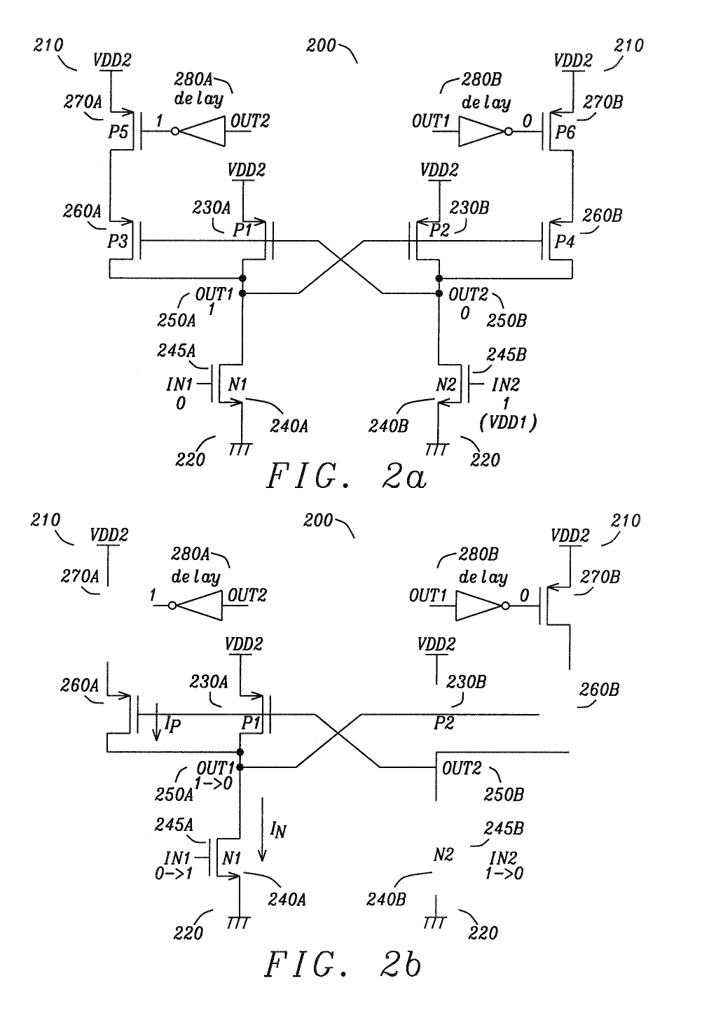

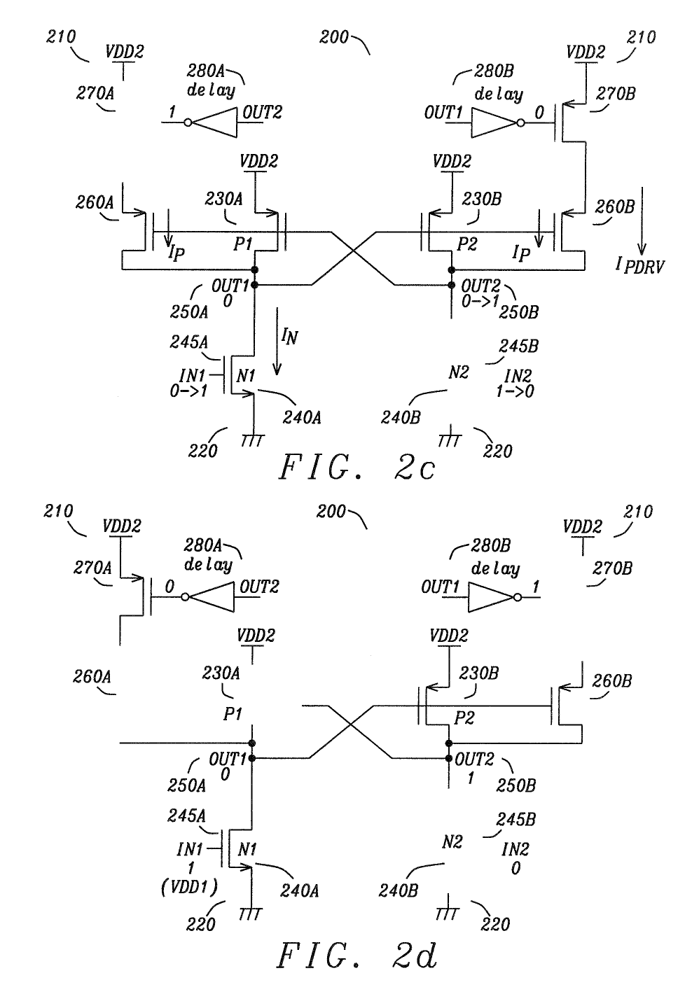

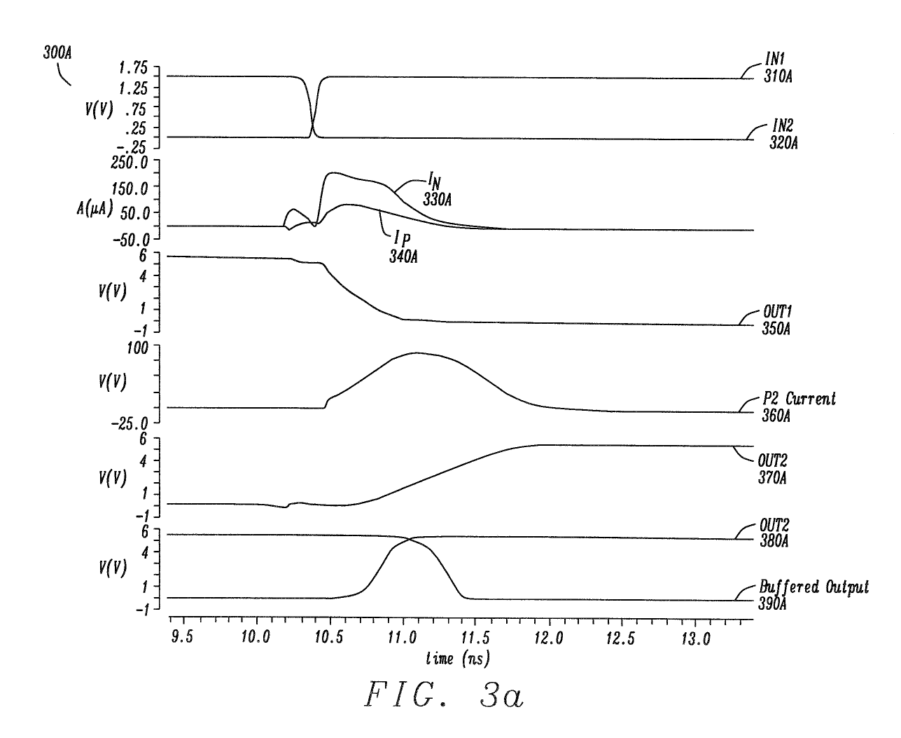

FIG. 2a to FIG. 2d is a circuit schematic in accordance with a first embodiment of the disclosure. FIG. 2b to FIG. 2d depicts a Transition Phase 1, Transition Phase 2, and an inverted state of FIG. 2a, respectively. FIG. 2a illustrates a level shift circuit 200, with a high power supply voltage (VDD2) 210, and ground (VSS) 220. The circuit 200 comprises a first n-channel metal oxide semiconductor (NMOS) N1 240A, with gate 245A having an input IN1. The circuit 200 comprises a second NMOS N2 240B, with gate 245B having an input IN2. The circuit 200 comprises a first PMOS P1 230A, with its gate coupled to signal OUT2 250B.

The circuit 200 comprises a second PMOS P2 230B, with its gate coupled to signal OUT1 250A. An auxiliary transient pair network is in parallel with the level shift network. PMOS P3 260 is placed in parallel to PMOS P1, and PMOS P4 260B is placed in parallel to PMOS P2. The PMOS P5 270A is placed in series cascode configuration with PMOS P3 260A. The PMOS P6 270B is placed in series cascode configuration with PMOS P4 260B. An inverter circuit 280A provides a delay signal whose input is OUT2 and output is coupled to the gate of PMOS P5 270A. An inverter circuit 280B provides a delay signal whose input signal is OUT1 and output is coupled to the gate of PMOS P5 270B. FIG. 2a illustrates the state of IN1 245A and OUT2 250B being low (“0”) and IN2 245B and OUT1 250A high (“VDD1” and “VDD2”, respectively).

FIG. 2b and FIG. 2c illustrates transition phases when the input signals (IN1, IN2) transition from the logic state of (0,1) to (1,0). In the Phase 1, OUT1 250A is pulled downward from VDD2 to ground (e.g. VSS), as illustrated in FIG. 2(B). In this state, since both NMOS N1 240A and PMOS P1 230A are in an “on” state, the speed is dependent on the difference of the current between the two transistors (e.g. I_{N}-I_{P}). The current flow in the p-channel MOSFET P1 230A is from VDD2 to ground (e.g. VSS).

The transition phase 1 fall time (tf) of OUT1 can be expressed as

tf=Cp VDD/(I_{N}−I_{P})

where Cp is the parasitic capacitance at the output OUT1, and where IP can be minimized. The energy loss due to “shoot through” current (where the shoot through current is the current flowing from VDD2 to ground during this phase) can be expressed as

{I_{P}/I_{N}}C_{P} V_{DD2}²

During the transition phase 2, a rise time (t_{R}) at OUT2 is

t_{R}=C_{P}V_{DD2}/I_{PDRV}

and the propagation delay is equal to

C_{P}V_{DD2}(1/I_{N}+1/I_{PRDV}).

If I_{PDRV} of the disclosure is the same as I_{P} of the prior art, the delay is the same, then the NMOS N1 and N2 size can be half as wide. In an example use of the level shifter of the disclosure in conjunction with a buck-boost converter, the V_{DD1} is approximately 2.5V to 5V, and V_{DD2} is 2.8V to 3.6V. As a result, the PMOS width of the prior art needs to be optimized for the worst case corner of PMOS (e.g. 2.8V) and NMOS width needs to be optimized for the worst case corner (e.g. 2.5V) but the best corner of the PMOS (e.g. 3.6V).

FIG. 2c illustrates the second transition phase, the signal OUT2 250B is pulled up from ground (e.g. VSS) to VDD2. In this state, OUT2 is pulled up by PMOS P2 230B, and equivalently OUT2 is pulled up by PMOS P4 260B and PMOS P6 270B. Hence the pull-up current is I_{P}+I_{PDRV}. Therefore, the pull-up speed can be defined as I_{PDRV} which is independent of the pull-down speed. Hence transistor PMOS P1 230A and PMOS P2 230B can be minimized (e.g. the MOS width can be reduced) and the current flow from VDD2 to ground (e.g. VSS) is minimized.

If the delay circuit (e.g. 280A and 280B delay circuit blocks) is composed of MOS elements with small drive current, PMOS P1 230A and PMOS P2 230B are on until transition phase 2 is finished. With the addition of the auxiliary current path, the design size of the PMOS pair and the NMOS pair can be independent variables; this allows for design freedom of variables and avoids design variable constraints. Hence, NMOS and PMOS widths can be decided independently, allowing for area reduction in the optimization method. In this disclosure, the NMOS and PMOS widths are independent, as well as having a reduced layout area of 20%.

FIG. 2d illustrates the “inverted state” after the transition phase 2 state. Note that this inverted state is opposite state of the state in FIG. 2a with opposite states for IN1, IN2, OUT1, and OUT2.

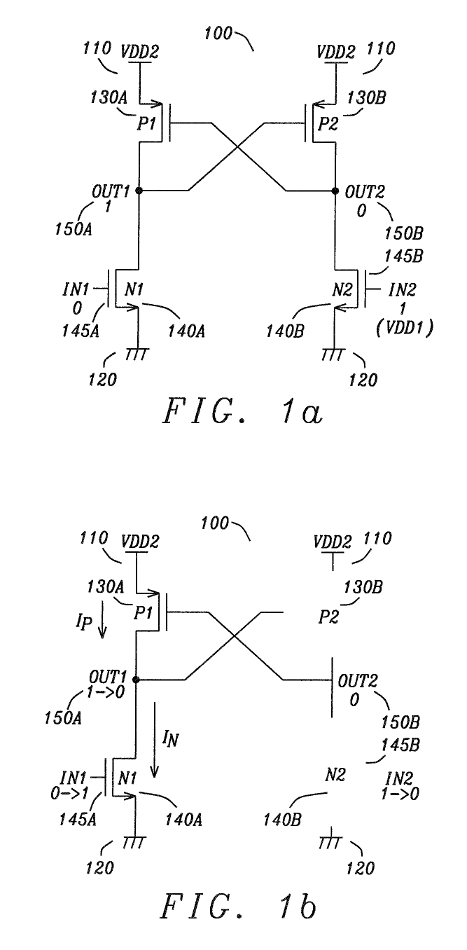

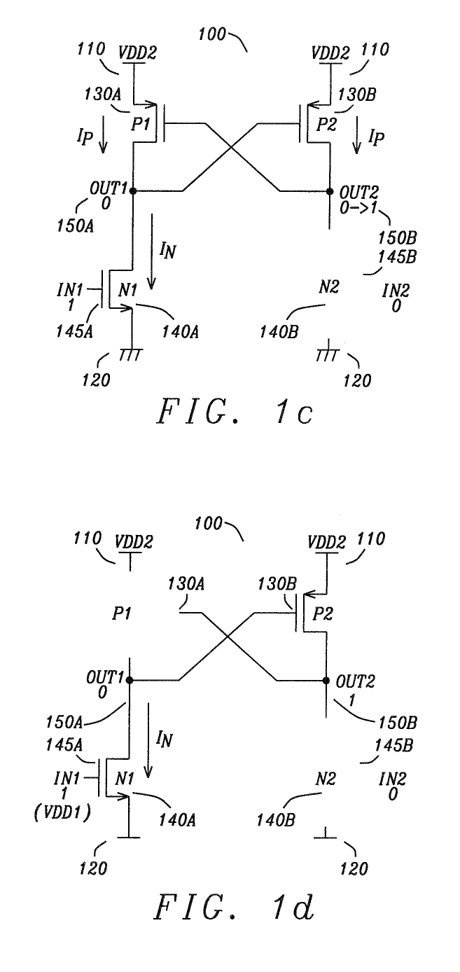

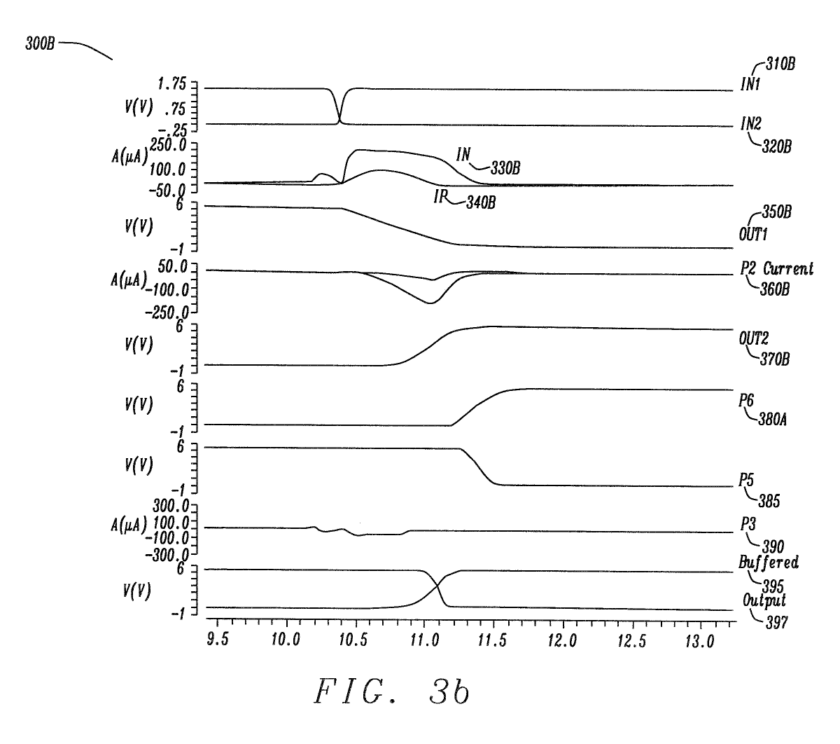

FIG. 3a and FIG. 3b is a timing diagram of the level shift circuit known to the inventor, and a timing diagram in accordance with the disclosure of FIG. 1, respectively.

For FIG. 3a, the signals of the circuit in FIG. 1a to 1d are shown. The signals for voltage and current as a function of time are shown in FIG. 3a for the embodiment known to the inventor 300A, and FIG. 3b for the first embodiment of the disclosure 300B. The plot 310A and 320A shows the IN1 signal and IN2 signal, respectively. The plot 330A and plot 340A illustrates the current I_{N} and I_{P}, respectively. The plot 350A is the voltage for signal OUT1. The plot 360A is the current in transistor P2. The plot 370A is the voltage for signal OUT2. The plot 380A and the plot 390A are the voltages of the buffered output signals.

For FIG. 3b, the signals of the circuit in FIGS. 2a to 2d are shown. The signals for voltage and current as a function of time are shown in FIG. 3b for the first embodiment of the disclosure 300B. The plot 310B and 320B shows the IN1 signal and IN2 signal, respectively. The plot 330B and plot 340B illustrates the current I_{N} and I_{P}, respectively. The plot 350B is the voltage for signal OUT1. The plot 360B is the current IP and IPDRV. The plot 370B is the voltage for signal OUT2. The plot 380A is the voltage on transistor gate of P6. Plot 385 is the voltage on the gate of transistor P5. Plot 390 is the current in transistor P3. Lastly, are the voltage signals for the buffered outputs as signals 395 and 397.

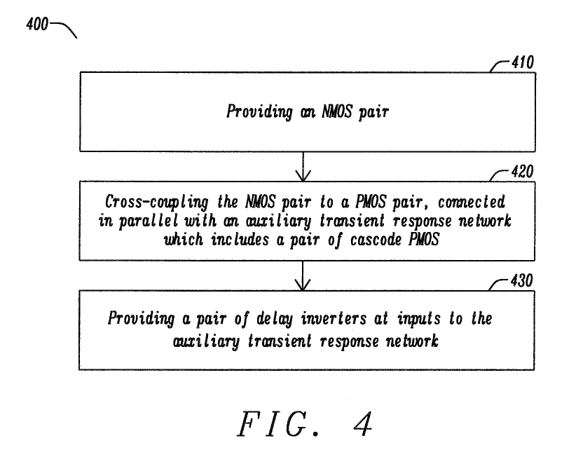

FIG. 4 illustrates a method in accordance with an embodiment of the disclosure. A method 400 of providing a level shift circuit is shown, including a first step 410 providing an NMOS pair, a second step 420 cross-coupling the NMOS pair to a PMOS pair, connected in parallel with an auxiliary transient response network which includes a pair of cascode PMOS, and a third step 430 providing a pair of delay inverters at inputs to the auxiliary transient response network.

It should be noted that the description and drawings merely illustrate the principles of the proposed methods and systems. It will thus be appreciated that those skilled in the art will be able to devise various arrangements that, although not explicitly described or shown herein, embody the principles of the invention and are included within its spirit and scope. The role of the transistors serve as “switches.” Hence it is in the spirit and scope of the application to have different types of switches from MOS switches, LDMOS switches to bipolar junction transistors.

It should be noted that the description and drawings merely illustrate the principles of the proposed methods and systems. It will thus be appreciated that those skilled in the art will be able to devise various arrangements that, although not explicitly described or shown herein, embody the principles of the invention and are included within its spirit and scope. Furthermore, all examples recited herein are principally intended expressly to be only for pedagogical purposes to aid the reader in understanding the principles of the proposed methods and systems and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass equivalents thereof.

Other advantages will be recognized by those of ordinary skill in the art. The above detailed description of the disclosure, and the examples described therein, has been presented for the purposes of illustration and description. While the principles of the disclosure have been described above in connection with a specific device, it is to be clearly understood that this description is made only by way of example and not as a limitation on the scope of the disclosure.

What is claimed is:

1. A level shifting circuit, comprising
an NMOS pair;
a PMOS pair cross-coupled to said NMOS pair; and
an auxiliary transient response network parallel to said PMOS pair configured to provide a parallel current path; and
a delay network configured to provide a delay to said auxiliary transient response network.

2. The level shift circuit of claim 1 wherein said auxiliary transient response network comprises a series cascode transistor pair configured in parallel with said PMOS pair.

3. The level shift circuit of claim 1 wherein said delay network is coupled to provide first and second output signals to said auxiliary transient response network.

4. The level shift circuit of claim 1 wherein said NMOS pair is coupled to a ground supply.

5. The level shift circuit of claim 1 wherein the gates of said NMOS pair are coupled to a first and second input signal.

6. The level shift circuit of claim 1 wherein said PMOS pair and said auxiliary transient response network are coupled to a different voltage level than that used for inputs signals to said circuit.

7. The level shift circuit of claim 1 wherein inputs for said delay network are coupled to first and second output signals.

8. The level shift circuit of claim 1 wherein the transient pull-up speed is a function of the parallel combination of the PMOS current drive of said PMOS pair and current drive of said auxiliary transient response network.

9. The level shift circuit of claim 8 wherein during a first transition phase a fall time, tf, of a first output signal is Cp VDD/(I_{N}−I_{P}), wherein Cp is parasitic capacitance at the output, V_{DD} is a power supply voltage, where I_{N} is current flow through one NMOS of said NMOS pair, I_{P} is current flow through one of the PMOS of said PMOS pair wherein I_{P} is minimized.

10. The level shift circuit of claim 6 where the energy loss due to “shoot through” current is the inverse ratio of the current flow through one of NMOS of said NMOS pair I_{N} and one of the PMOS of said PMOS pair I_{P}, and a product of said second power supply evaluated as {I_{P}/I_{N}} C_{P} V_{DD2}² .

11. The level shift circuit of claim 10 wherein during a second transition phase rise time of each output signal is t_{R} where t_{R}=C_{P} V_{DD2}/I _{PDRV} where I_{PDRV} is the drive current of said auxiliary transient response network.

12. The level shift circuit of claim 11 wherein the propagation delay is equal to Cp V_{DD2} (1/I_{N}+1/I_{PDRV})

13. A level shift circuit of claim 1 wherein said delay network comprises a pair of inverters.

14. A method of providing a level shift circuit, comprising the steps of:
providing an NMOS pair
cross-coupling said NMOS pair to PMOS pair, connected in parallel with an auxiliary transient response network comprising a pair of cascode PMOS, and providing a pair of delay inverters at inputs to said auxiliary transient response networks.

15. The method of claim 14, further comprising the steps of:
choosing the width of said NMOS pair.

16. The method of claim 15, further comprising the steps of choosing the PMOS width of said auxiliary transient response network.

17. The method of claim 16, further comprising the steps of:
optimize said auxiliary transient response network by increasing drive current I_{PDRV}.

18. The method of claim 17, further comprising the steps of:
minimize said PMOS pair width.

19. The method of claim 18 wherein said auxiliary transient response network provides design freedom to allow minimization of said PMOS pair width.

20. The method of claim 18 allows for minimization of area.

21. The method of claim 18 allows for minimization of said propagation delay.
